(19) United States
(12) Patent Application Publication
(10) Pub. No.: US 2010/0151119 A1
(43) Pub. Date: Jun. 17, 2010

(54) VACUUM VESSEL, VACUUM PROCESSING APPARATUS INCLUDING VACUUM VESSEL, VACUUM VESSEL MANUFACTURING METHOD, AND ELECTRONIC DEVICE MANUFACTURING METHOD

(75) Inventor: Masao SASAKI, Hachioji-shi (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/638,071

(22) Filed: Dec. 15, 2009

(30) Foreign Application Priority Data
Dec. 17, 2008 (JP) 2008-320829

(51) Int. Cl. B05D 5/12; B65D 81/20; C23C 14/00; B23P 17/00

(52) U.S. Cl. 427/58; 206/524.8; 118/50; 29/428

(57) ABSTRACT

A vacuum vessel includes a pair of bending members which are formed by bending metal plates in predetermined shapes and are bonded to each other to form a closed space inside them. The vacuum vessel also includes a sealing member which seals the gap in the bonding portion between the bending members, and a cubic lattice structure which abuts against the inner surfaces of both the bending members and is accommodated in the closed space. The vacuum vessel further includes a magnet unit. The magnet unit fixes the bending members onto the structure and seals the gap in the bonding portion between the bending members by pressing an O-ring serving as a sealing member along the bonding portion.

### BACKGROUND OF THE INVENTION

1. Field of the Invention

The present invention relates to a vacuum vessel such as a process chamber or transfer chamber that constitutes a vacuum processing apparatus which processes, for example, a liquid crystal display substrate and a semiconductor wafer, a vacuum processing apparatus including the vacuum vessel, a vacuum vessel manufacturing method, and an electronic device manufacturing method.

2. Description of the Related Art

Processes such as thin-film formation on, for example, a liquid crystal display substrate and a semiconductor wafer and dry etching and heating of the formed thin films are mainly performed in a vacuum. Alignment, transportation, and the like of these processing objects in preparation for processing them in a vacuum are often continuously performed in a vacuum as well. To perform these processes, a vacuum processing apparatus formed by connecting a plurality of vacuum vessels via gate valves is commonly used (Japanese Patent Laid-Open No. 2002-057203).

In recent years, liquid crystal display substrates are increasingly growing in size. As a result, even a rectangular substrate with a side length longer than 3 meters in its periphery has become available. To process such a large substrate in a vacuum, a large vacuum vessel is necessary. A small vacuum vessel with excellent airtightness can be manufactured by cutting the interior of a single metal material. However, large vacuum vessels cannot be manufactured by the method mentioned above for manufacturing small vacuum vessels because of the difficulty in obtaining such large metal elements.

Under these circumstances, a conventional large vacuum vessel is formed so as to maintain airtightness by ensuring a given mechanical strength by welding a combination of a plurality of metal plate members in given weld zones.

However, vacuum vessels manufactured in this manner are undesirably heavy. In addition, the manufactured vacuum vessel often undesirably suffers thermal strain due to factors associated with welding. For this reason, secondary cutting is necessary after welding in this method. Furthermore, a large welded vacuum vessel is often hard to transport because its transportation is hampered by, for example, the limits of the acceptable weight, width, and height of transportation vehicles and certain legal restrictions.

To combat these problems, a combination of two bent metal plates is often used to form a closed space. The inventors of the present invention have examined a vacuum vessel which maintains the formed closed space airtight by accommodating a robust structure in the closed space, and sealing the bonding portion between the metal plates by one sealing member formed in a closed curve.

The inventors of the present invention have also examined a method of securely fixing the metal plates onto a column serving as a structure present inside the vessel by bolts to fix the bonding portion between the metal plates.

FIGS. 17 and 18 are, respectively, an external view of the vacuum vessel examined by the inventors of the present invention, and a sectional view of the bonding portion in the vacuum vessel.

As shown in FIGS. 17 and 18, two metal plates (bending members 20 and 30) are securely fixed on a column 50 serving as a structure present inside the vessel by fastener members 61 and 62 such as bolts and seal fixing plates 63 and 64.

However, such a method of fixing the bonding portion between the two metal plates poses the following problem. Because the two metal plates are fixed on the structure inside the vessel by bolts in order to reliably squeeze an O-ring serving as a sealing member 4 corresponding to the bonding portion between the two metal plates, the vacuum vessel is easy to evacuate but has a complicated structure.

To fix the metal plates (bending members 20 and 30) serving as the vessel walls onto the column 50 inside the vacuum vessel by bolts, it is necessary to form, in the vessel walls, holes 20a and 30a to insert the bolts and it is, in turn, necessary to maintain the closed space airtight by disposing other O-rings 65 and 66 around the holes 20a and 30a. For this reason, multiple hole formation and sealing surface fabrication are necessary for the two metal plates. This is problematic due to a subsequent increase in manufacturing cost and degradation in reliability of vacuum performance.

The present invention has been made in consideration of the problems of the above-mentioned background art, and has as its object to improve the airtightness in the bonding portion between plate members which form a vacuum vessel with a simple structure.

### SUMMARY OF THE INVENTION

According to one aspect of the present invention, there is provided a vacuum vessel including a plurality of plate members each of which is partially or wholly made of a metal and which are bonded to each other to form a closed space inside the plate members, and a sealing member which seals the bonding portion between the plate members, comprising:

a structure which is accommodated in the closed space, abuts against inner surfaces of the plate members and the sealing member, and is wholly or partially formed from a ferromagnetic body; and

a permanent magnet which is disposed on an outer surface of the plate member and presses the plate member against the sealing member by a magnetic attractive force acting on the ferromagnetic body of the structure.

According to another aspect of the present invention, there is provided a vacuum vessel including a pair of plate members which are formed by bending metal plates and are bonded to each other to form a closed space inside the plate members, and one sealing member which is formed in a closed curve and seals the bonding portion between the pair of plate members, comprising:

a structure which is accommodated in the closed space, abuts against inner surfaces of the plate members and the sealing member, and is wholly or partially formed from a ferromagnetic body; and

a permanent magnet which is disposed on an outer surface, opposite to the inner surface, of the plate member and presses the plate member against the sealing member by a magnetic attractive force acting on the ferromagnetic body of the structure.

According to still another aspect of the present invention, there is provided a vacuum vessel manufacturing method comprising:

a first step of bending metal plates to form a pair of plates which are bonded to each other to form a closed space inside the plate members;

a second step of accommodating, in the closed space, a structure which is wholly or partially formed from a ferromagnetic body and abuts against inner surfaces of the plate members, and interposing one sealing member, which is formed in a closed curve and seals the bonding portion between the pair of plate members, between the inner surfaces of the pair of plate members and an outer surface of the structure along the bonding portion; and

a third step of disposing a plurality of permanent magnets on outer surfaces, opposite to the inner surfaces, of the pair of plate members, and pressing the pair of plate members against the sealing member by magnetic attractive forces acting on the magnetic body of the structure.

According to yet another aspect of the present invention, there is provided a vacuum processing apparatus comprising:

a process chamber which comprises the above-mentioned vacuum vessel and processes an object under a reduced-pressure atmosphere in the vacuum vessel.

According to still yet another aspect of the present invention, there is provided an electronic device manufacturing method comprising a step of:

processing an object using the above-mentioned vacuum processing apparatus.

According to the present invention, since a sealing member corresponding to the bonding portion between metal plates which form a vacuum vessel can be reliably squeezed without using, for example, bolts which fasten the metal plates, the vacuum vessel is easy to evacuate and has a highly reliable vacuum performance. It is also possible to reduce the manufacturing cost of the vacuum vessel because of its simple structure. Moreover, it is easy to manufacture a vacuum vessel.

Further features of the present invention will become apparent from the following description of exemplary embodiments with reference to the attached drawings.

### BRIEF DESCRIPTION OF THE DRAWINGS

FIG. 1 is an external view of a vacuum vessel according to one embodiment of the present invention;

FIG. 2 is an exploded perspective view of the vacuum vessel, in which a magnet unit shown in FIG. 1 is not illustrated;

FIG. 3 is a view for explaining a pair of bending members shown in FIG. 1;

FIG. 4 is a view for explaining a structure shown in FIG. 1;

FIGS. 5A to 5C are views showing examples of the arrangement of columns which form the structure shown in FIG. 1;

FIG. 6 is a view showing an O-ring serving as a sealing member shown in FIG. 1;

FIG. 7 is a sectional view of the bonding portion between the bending members shown in FIG. 1;

FIG. 8 is an external view of the magnet unit shown in FIG. 1 while a cover is detached from it;

FIG. 9 is a view showing the state in which the cover is attached to the magnet unit shown in FIG. 8;

FIG. 10 is a sectional view taken along a line A-A in FIG. 7;

FIG. 11 is a sectional view of a magnet unit disposed in correspondence with the bending portion of the bending member shown in FIG. 1;

FIG. 12 is a front view of a magnet unit disposed in correspondence with the corner of the bending member shown in FIG. 1;

FIG. 13 is a sectional view showing the first modification (a case in which four magnets are present) of the magnet unit shown in FIG. 1;

FIG. 14 is a sectional view showing the second modification (a case in which one magnet is present) of the magnet unit shown in FIG. 1;

FIG. 15 is a sectional view of a column as a modification of the column which forms the structure shown in FIG. 1;

FIG. 16 is a view illustrating one example of a vacuum processing apparatus to which the vacuum vessel according to the embodiment of the present invention is applied;

FIG. 17 is an external view of a vacuum vessel which has the problems to be solved by the present invention and was examined by the inventors of the present invention;

FIG. 18 is a sectional view of the bonding portion between bending members shown in FIG. 17; and

FIG. 19 is a sectional view showing the cross-sectional structure of an a-Si TFT (Thin Film Transistor).

### DESCRIPTION OF THE EMBODIMENTS

Detailed embodiments of the present invention will be described below with reference to the accompanying drawings.

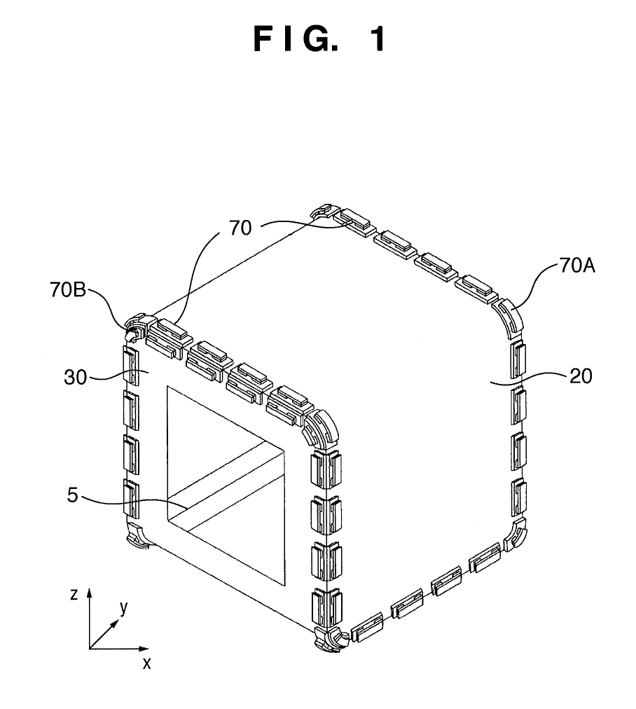

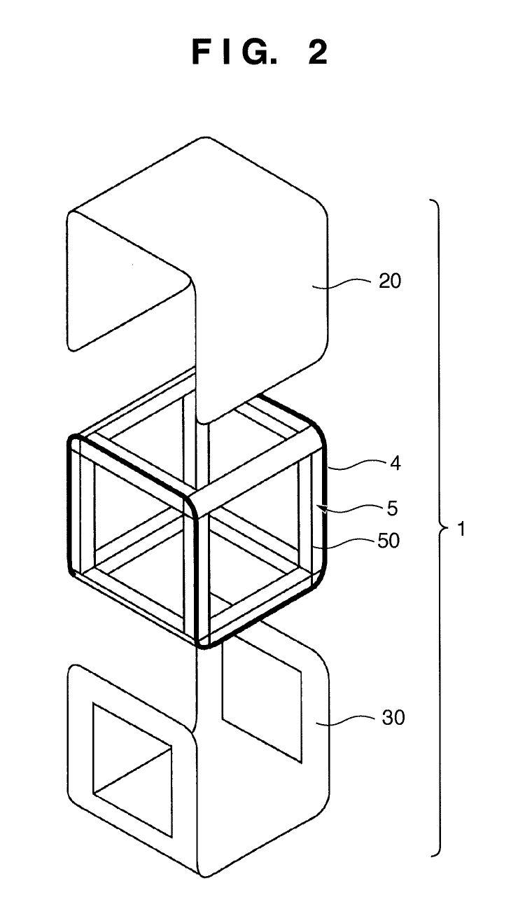

FIG. 1 shows a vacuum vessel according to one embodiment of the present invention. This embodiment will exemplify a hexahedral vacuum vessel. FIG. 2 is an exploded perspective view of the vacuum vessel shown in FIG. 1.

As shown in FIGS. 1 and 2, a vacuum vessel 1 includes a pair of bending members 20 and 30. The bending members 20 and 30 are formed by bending metal plates into predetermined shapes. The vacuum vessel 1 is formed by bonding the bending members 20 and 30 to each other so as to form a closed space inside them. The vacuum vessel 1 also includes a sealing member 4 and cubic lattice structure 5. The sealing member 4 seals the gap in the bonding portion between the bending members 20 and 30. The structure 5 is accommodated in the closed space while abutting against the inner surfaces of the bending members 20 and 30. The vacuum vessel 1 still also includes magnet units 70 including, for example, permanent magnets. The magnet units 70 fix the bending members 20 and 30 onto the structure 5 and press an O-ring serving as the sealing member 4 along the bonding portion between the bending members 20 and 30 in order to seal the bonding portion.

The bending members 20 and 30 need only be made of at least a material which has both a given mechanical strength and machinability so that a combination of two bending members made of it can form one closed space.

Each of the bending members 20 and 30 is one relatively thin plate member and is formed by bending a metal plate with a desired mechanical strength. The bonding portion between the bending members 20 and 30 is airtightly sealed by one sealing member 4 formed in a closed curve (one continuous curve). The space surrounded by the two bending members 20 and 30 forms the vacuum vessel 1. The vacuum vessel 1 is maintained airtight by the two bending members 20 and 30 and one sealing member 4 formed in a closed curve.

In the arrangement according to this embodiment, the vacuum vessel 1 forms a hexahedron and has the structure 5 with a desired rigidity. The structure 5 in this embodiment includes columns 50 located in portions corresponding to the sides of the faces of the hexahedron, and so is formed in a cubic lattice pattern, according to which these 12 columns 50 are integrated. The structure 5 is set in a vacuum surrounded by the pair of bending members 20 and 30, and supports the vacuum vessel 1 in order to withstand the atmospheric pressure applied to the vacuum vessel 1 to suppress deformation of the vacuum vessel 1.

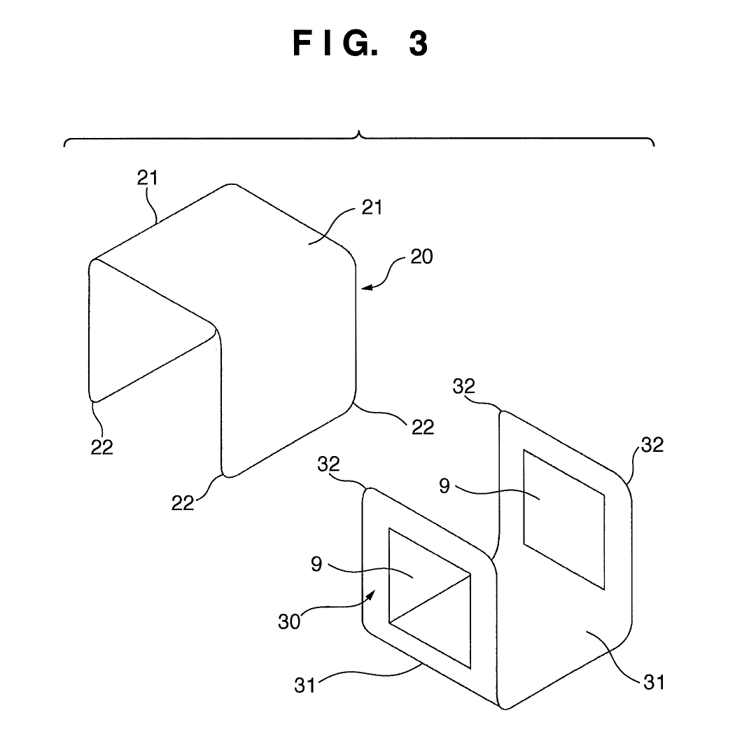

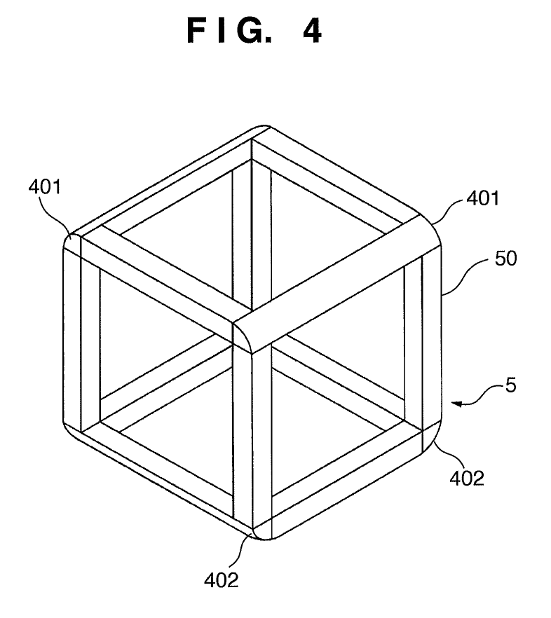

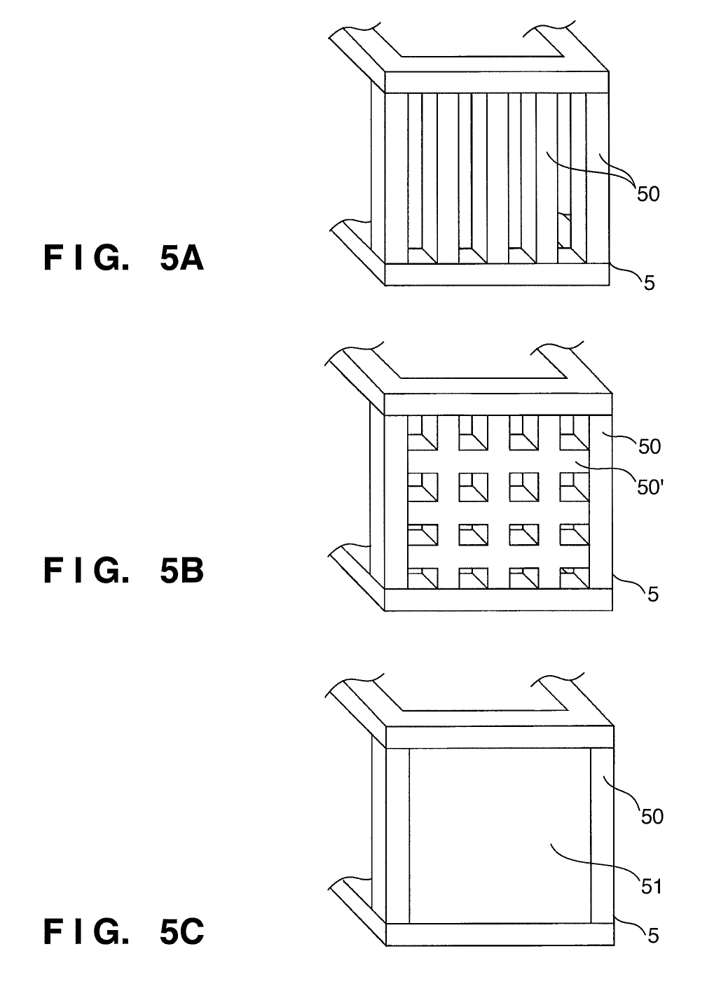

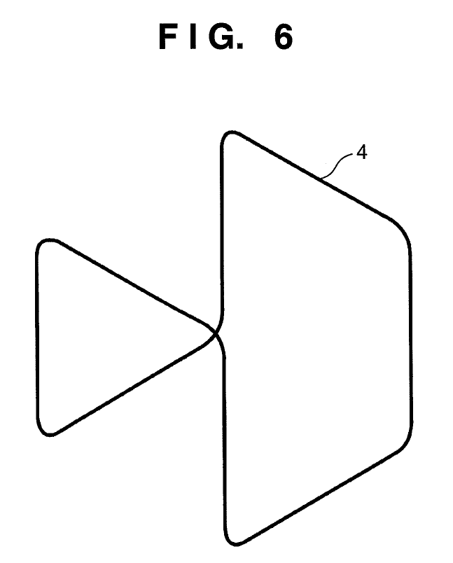

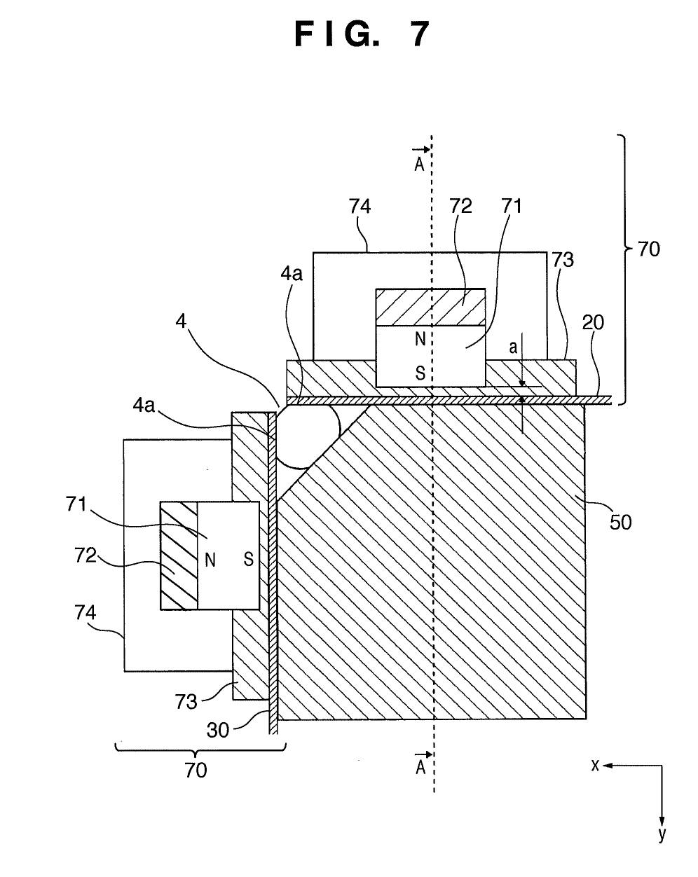

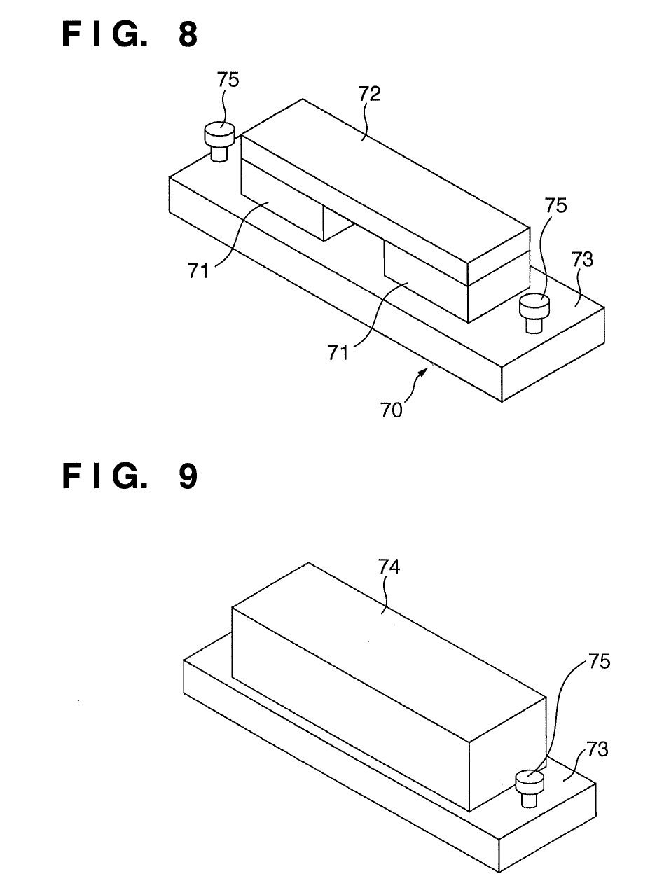

The bending members 20 and 30 which form the vacuum vessel 1 will be explained with reference to FIG. 3, and the structure 5 will be explained with reference to FIGS. 4 and 5. Also, the sealing member 4 will be explained with reference to FIG. 6, and the bonding structure between the pair of bending members 20 and 30 will be explained with reference to FIG. 7. Further, the magnet units 70 will be explained with reference to FIGS. 8 through 14.

The bending members 20 and 30 which form the vacuum vessel 1 will now be explained first with reference to FIG. 3.

As shown in FIG. 3, the pair of bending members 20 and 30 each are formed by, for example, longitudinally bending one plate-like rectangular metal plate into a U shape.

The inner surfaces of the bending members 20 and 30 when they are bent in a U shape correspond to the vacuum side of the vacuum vessel 1 and therefore serve as those of the vacuum vessel 1. The bending member 20 has two bending portions 21 formed on it. Similarly, the bending member 30 has two bending portions 31 formed on it.

The two bending portions 21 and 31 are linear creases in which the bending members 20 and 30 are bent along straight lines parallel to the widthwise direction. Thus, each of the bending portions 21 and 31 forms one side of a hexahedron which forms the closed space serving as the vacuum vessel 1. The shape of the vacuum vessel to form the closed space is not limited to a hexahedron, and may be a polyhedron defined by, for example, three or more side surfaces and two bottom surfaces.

In this embodiment, the bending portions 21 and 31 are bent at a right angle. Also, the bending portions 21 and 31 have a bending radius of curvature of about 100 mm to 300 mm and an arcuated cross-section. Note that setting a relatively small radius of curvature for the bending portions 21 and 31 is unpreferable because this produces nonuniformities in the surfaces of metal plates being bent.

As will be described later, the vacuum vessel 1 formed by bonding the pair of bending members 20 and 30 is maintained airtight by the sealing member 4 (see FIG. 2) such as an O-ring and by conditioning the surface states of the bending members 20 and 30 which form the vacuum vessel 1.

For this reason, it is necessary to smoothen the surfaces of the bending members 20 and 30 in their portions where the bending members 20 and 30 come into contact with the sealing member 4. In view of this, setting a relatively large bending radius of curvature for the bending portions 21 and 31 can suppress the occurrence of nonuniformities in the surfaces of the bending members 20 and 30, resulting in good contact characteristics with the sealing member 4.

Four corners 22 and four corners 32 of the bending members 20 and 30, respectively, similarly have a radius of curvature of about 100 mm to 300 mm and are cut in an arc. This is to make the radius of curvature of the corners 22 and 32 equal to the bending radius of curvature of the bending portions 21 and 31 of the bending members 20 and 30, which are respectively combined with the corners 32 and 22, when bonding the bending members 20 and 30.

The vacuum vessel 1 generally has openings 9 formed in it to transfer a substrate into the vacuum vessel 1 and to accommodate various kinds of devices. In this embodiment, the bending member 30 is configured such that rectangular openings 9 are formed in two opposing flat surfaces. The openings 9 accommodate other vacuum vessels, devices, or lids to ultimately maintain airtightness in the interior of the vacuum vessel 1.

The bending members 20 and 30 can be made of a nonmagnetic metal material such as aluminum or nonmagnetic stainless steel. The bending members 20 and 30 preferably have a thickness of about 0.1 mm to 3 mm. The formation of bending members to have such a thickness makes it possible to easily bend them and smoothen the surfaces in their bending portions. Bending members that are too thick produce nonuniformities in the surfaces in their bending portions upon bending, and this makes it difficult to seal the vacuum vessel 1. In contrast, bending members that are too thin cause deformation upon evacuation of the vacuum vessel 1 or make it impossible to reliably squeeze the sealing member 4 such as an O-ring, and this again makes it difficult to seal the vacuum vessel 1.

Making the bending members 20 and 30 out of a ferromagnetic metal is unpreferable because this reduces the magnetic attractive forces of the magnet units 70 to the structure 5 (to be described later). However, when the bending members 20 and 30 are sufficiently thin, they can be made of a ferromagnetic material because the magnet units 70 can attract the structure 5 although their magnetic attractive forces acting on it weaken slightly.

FIG. 4 illustrates an example of the arrangement of the structure 5.

In this embodiment, the structure 5 includes the 12 columns 50 present at positions corresponding to the sides of the faces of a hexahedron. The column 50 is made of a rigid metal material that wholly or partially contains a ferromagnetic material. The ferromagnetic material used is, for example, SUS430 or iron. A case in which the column 50 is wholly made of a ferromagnetic material will be exemplified herein, and that in which the column 50 is partially made of a ferromagnetic material will be described later.

Each column 50 is fixed by fastening bolts (not shown) and assembled to have a mechanical strength large enough to support the vacuum vessel 1 against the atmospheric pressure applied to the vacuum vessel 1. Since all the columns 50 are accommodated in the vacuum vessel 1, they need not undergo any processes for maintaining the airtightness of the vacuum vessel 1. This, in turn, makes it unnecessary to weld the columns 50 to each other and form sealing surfaces on the columns 50.

The outer shapes of the columns 50 are formed in conformity to the inner surface shapes of the vacuum vessel 1, which are formed by combining the two bending members 20 and 30. Accordingly, of the 12 sides of a hexahedron which forms the structure 5, four sides have curved surfaces formed on them, conforming to the inner surface shapes of the vacuum vessel 1. In other words, the structure 5 has curved portions 401 and 402 formed on it, which have curvatures corresponding to the bending portions 21 and 31 of the bending members 20 and 30.

FIGS. 5A to 5C show other examples of the arrangement of the structure 5. In the arrangement example shown in each of FIGS. 5A to 5C, the structure 5 has curved portions 401 and 402 formed on it, which have curvatures corresponding to the bending portions 21 and 31 of the bending members 20 and 30. For the sake of good visibility of the structure of the column 50, FIGS. 5A to 5C do not illustrate the curved portions 401 and 402.

The structure 5 shown in FIG. 4 includes the columns 50 located on only the sides of a hexahedron. Therefore, portions (e.g., the central portions of the faces) where the columns 50 do not support the inner surfaces of the bending members 20 and 30 may deform due to the atmospheric pressure. If the deformation of the vacuum vessel 1 becomes large, the vacuum vessel 1 may fail to maintain the closed space airtight or may be damaged.

Under such circumstances, to further reduce deformation of the bending members 20 and 30 which form the inner walls of the vacuum vessel 1, the columns 50 which form the structure 5 can be equidistantly arranged in a palisade pattern, as shown in FIG. 5A. Alternatively, columns 50′ arranged in a lattice pattern, as shown in FIG. 5B, can also be interposed between the left and right columns 50. Or again, deformation of the inner walls of the vacuum vessel 1 can be greatly reduced by covering at least one surface surrounded by the columns 50 with a flat plate member 51, as shown in FIG. 5C.

On the other hand, increasing the number of columns 50 or covering a surface surrounded by the columns 50 with the flat plate member 51 results in increases in both weight and manufacturing cost of the vacuum vessel 1. Hence, the number of columns 50 which form the structure 5 is desirably set as small as possible within the allowance of deformation of the vacuum vessel 1.

FIG. 6 is a perspective view of an O-ring as one example of the sealing member 4. The sealing member 4 can be an O-ring made of a rubber material. For example, an O-ring formed in a continuous annular shape having a circular cross-section is used. As shown in FIGS. 2 and 6, the sealing member 4 can be deformed in the same shape as that of the bonding portion between the two bending members 20 and 30. The sealing member 4 seals the entire region of the bonding portion between the two bending members 20 and 30.

FIG. 7 is a sectional view for explaining the bonding state between the bending members 20 and 30 in this embodiment.

The sealing member 4 is clamped by three surfaces: one side surface of the column 50 and the inner surfaces of the bending members 20 and 30. The column 50 is fabricated such that its surface, which abuts against the sealing member 4, forms an angle of 45° with respect to the inner walls of the vacuum vessel 1, that is, the inner surfaces of the bending members 20 and 30. In this embodiment, the cross-sectional shape of a set of three surfaces surrounding the sealing member 4 is a right isosceles triangle.

At the position between the sealing member 4 and the bending member 20, and at the position between the sealing member 4 and the bending member 30, the sealing member 4 is pressed by the bending members 20 and 30 and therefore their contact portions are flat. The flat contact portions function as sealing portions 4a for maintaining the airtightness of the vacuum vessel 1. The sealing member 4 is supported by the columns 50. The interior of the vacuum vessel 1 is satisfactorily maintained airtight by sealing the entire region of the bonding portion between the bending members 20 and 30 by the sealing portions 4a.

The magnet units 70 are disposed in the outer peripheries of the surfaces of the bending members 20 and 30 on their atmospheric sides. The magnet units 70 are fixed so as to press the sealing member 4 throughout the entire region of the bonding portion between the bending members 20 and 30 and push the bending members 20 and 30 against the columns 50.

The magnet unit 70 includes magnets 71 as permanent magnets, a yoke 72 made of a ferromagnetic material, a seal fixing plate 73, and a cover 74.

The magnet 71 is a permanent magnet and produces an attractive force on the column 50 while its magnetic surface faces the column 50. The magnet 71 can be made of, for example, ferrite or neodymium. Since a ferrite magnet has a weak magnetic force, it is suitable for a small vacuum vessel. Since a large vacuum vessel naturally includes an O-ring of large diameter as the sealing member 4, a neodymium magnet with a strong magnetic force is suitable as the magnet 71 in a large vacuum vessel in order to reliably squeeze the O-ring.

The magnet 71 is fixed on the seal fixing plate 73. The seal fixing plate 73 is made of a rigid nonmagnetic material such as aluminum or nonmagnetic stainless steel. The seal fixing plate 73 requires a given thickness to maintain a given rigidity. At the same time, the seal fixing plate 73 needs to have a thickness at which the interval between the magnet 71 and the column 50 is narrow enough to allow the magnet 71 to produce a large attractive force. To meet these requirements, a recess conforming to the shape of the magnet 71 is formed in the portion where the magnet 71 is located, in the seal fixing plate 73 to fix the magnet 71 into the recess. With this structure, the interval between the magnet 71 and the column 50 can be relatively narrow in the portion where the magnet 71 is fixed, while maintaining a given rigidity of the seal fixing plate 73. At this time, a thickness a of the seal fixing plate 73 in the portion where the magnet 71 is fixed is about 1 mm. This thickness allows the magnetic force between the magnet 71 and the column 50 to be large enough to satisfactorily fix the bending member.

Seal fixing plates 73 are disposed along the outer peripheries of the bending members 20 and 30 in order to reliably squeeze the sealing member 4. The attractive forces of the magnets 71 are transferred to the seal fixing plates 73 to squeeze the sealing member 4. Although this embodiment exemplifies a case in which the seal fixing plates 73 squeeze the sealing member 4, the sealing member 4 can be squeezed by only the magnets 71 without the seal fixing plates 73 as long as the magnets 71 have roughly the same size as that of the seal fixing plate 73. In this case, however, when a plurality of magnets 71 are juxtaposed, adjacent magnets 71 attract each other, so they are hard to handle. Naturally, an arrangement including no seal fixing plates 73 is applicable to, for example, a small vacuum vessel including weak magnets.

The cover 74 is attached to the magnet unit 70 because it is dangerous to leave the magnet 71 that has a strong magnetic force exposed after the magnet unit 70 is located on the vacuum vessel 1. The cover 74 may be made of a nonmagnetic metal or a resin such as acrylate, and is spaced apart from the magnet 71 and yoke 72 to some extent. The yoke 72 will be described later.

FIGS. 8 to 10 show the detailed arrangement of the magnet unit 70.

FIG. 8 is a perspective view of the magnet unit 70. The magnet unit 70 includes two magnets 71, the yoke 72 which connects the magnets 71 to each other and is made of a ferromagnetic material, the seal fixing plate 73, and screws 75. Also, FIG. 9 illustrates a case in which the cover 74 is attached to the magnet unit 70 so as to surround the magnets 71 and yoke 72 for the sake of handling safety. Note that FIG. 1 shows the magnet unit 70 without the cover 74 for the sake of good visibility of its internal arrangement.

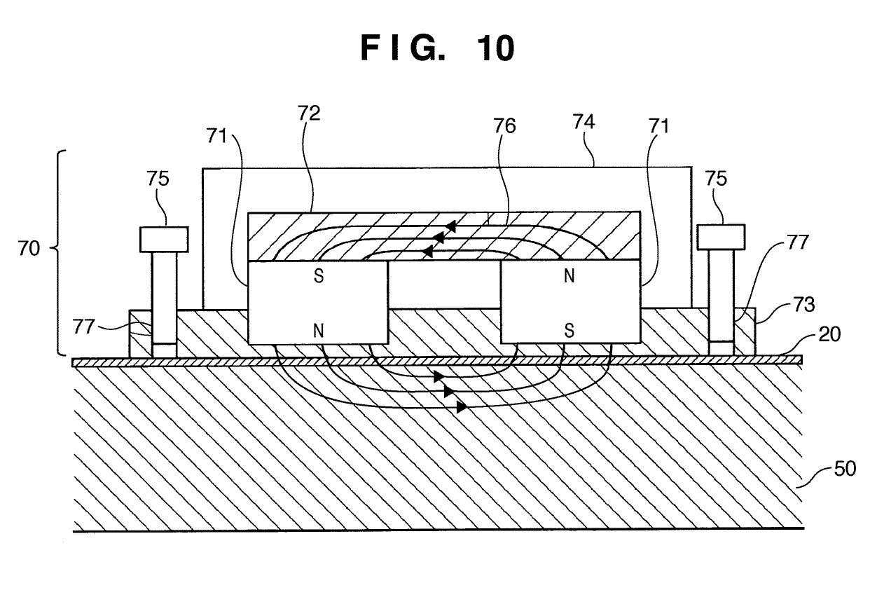

FIG. 10 is a sectional view taken along a line A-A in FIG. 7 when the magnet unit 70 is placed in the vacuum vessel 1.

The two magnets 71 are disposed such that their opposite magnetic poles face the column 50. The yoke 72 connects the surfaces of the two magnets 71 on the opposite side of the column 50. FIG. 10 shows magnetic lines of force 76 at this time. In this state, the magnetic lines of force 76 run almost completely through the columns 50 and the yoke 72 as a ferromagnetic body. A magnetic circuit thus formed is preferable because the magnetic flux density increases and the magnetic force, in turn, increases as compared with a case in which one magnet attracts the columns 50.

Two through screw holes 77 extend through the seal fixing plate 73, and screws 75 that are longer than the depth of the screw holes 77 are inserted in the screw holes 77. The screws 75 are used in detaching the magnet unit 70 from the vacuum vessel 1.

While the magnet unit 70 is fixed on the outer surface of the vacuum vessel 1, the leading ends of the screws 75 have not reached the positions at which they completely penetrate through the screw holes 77. Alternatively, the screws 75 may be pulled out and removed from the screw holes 77.

To assemble the vacuum vessel 1, it is often necessary to detach the magnet unit 70 placed in the vacuum vessel 1 for adjustment or for the sake of convenience associated with the assembly procedure. In this case, the screws 75 are rotated deep into the screw holes 77 until their leading ends project from the screw holes 77. The seal fixing plate 73 is separated from the bending member 20 by making the leading ends of the screws 75 project from the screw holes 77. With this operation, the magnet unit 70 is easily detached from the vacuum vessel 1. However, if weak magnets are used in the magnet unit 70, the operator also can directly detach it by hand without using any such a mechanism. In this case, the screws 75 are unnecessary.

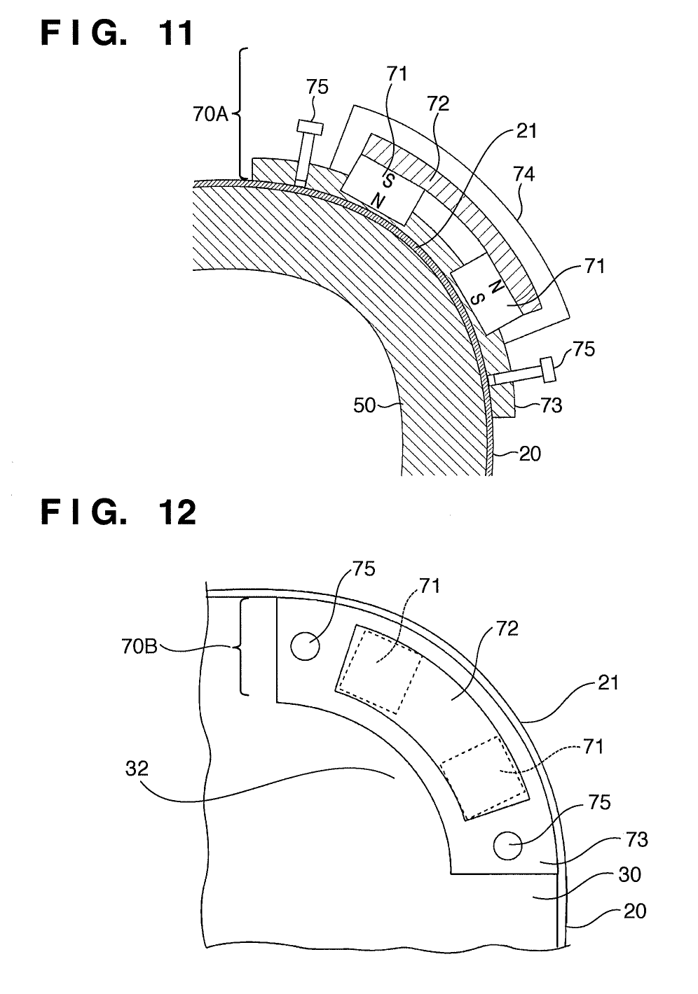

FIG. 11 is a sectional view illustrating a case in which an arcuated magnet unit 70A is located in the portion where the bending member 20 is bent (the bending portion 21 shown in FIG. 3). FIG. 12 is a front view showing a case in which an arcuated magnet unit 70B is located at the corner of the bending member (the corner 32 shown in FIG. 3).

The magnet units 70A and 70B have shapes changed in conformity to the surface shapes of the bending members in their portions where the magnet units 70A and 70B are located. However, the fundamental structures of the magnet units 70A and 70B are the same as that of the magnet unit 70 shown in FIGS. 7 to 10.

The above-described constituent components of the vacuum vessel 1 can be changed in the following manner as needed.

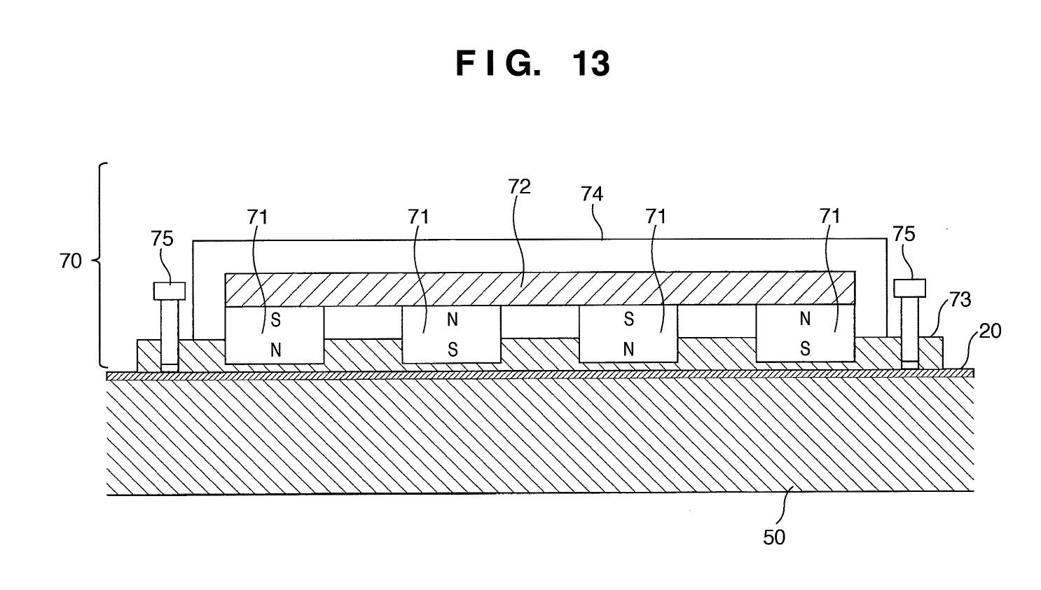

FIG. 13 is the first modification of the magnet unit 70, in which it includes four magnets 71. The four magnets 71 have magnetic pole directions which are alternately opposite to each other in turn from the end. The yoke 72 stretches over all the magnets 71 and connects them. Each magnet in such a magnetic circuit can produce a magnetic attractive force equal to that produced by two magnets. In this case, each magnet unit 70 is relatively long and so a relatively small number of magnet units 70 are used when a large vacuum vessel 1 is assembled, thus facilitating the assembly. When a plurality of magnets are juxtaposed in this way, a magnetic unit including four or more magnets 71 is also viable.

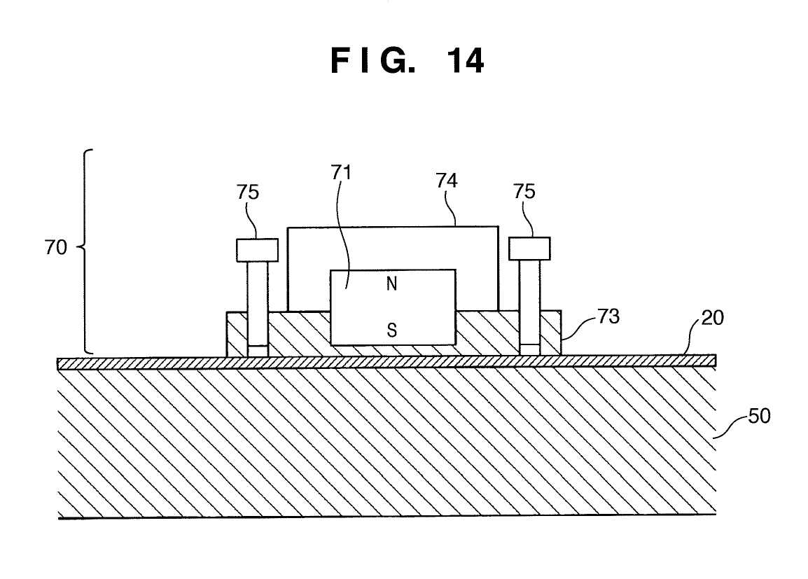

FIG. 14 is the second modification of the magnet unit 70, in which it includes one magnet 71. In this case, no yoke is necessary. A magnetic attractive force produced by one magnet 71 is weaker than that produced by two magnets 71, so the second modification is suitable for a small vacuum vessel. When the magnetic attractive force is relatively weak, the screws 75 for use in magnetic unit pullout may be absent.

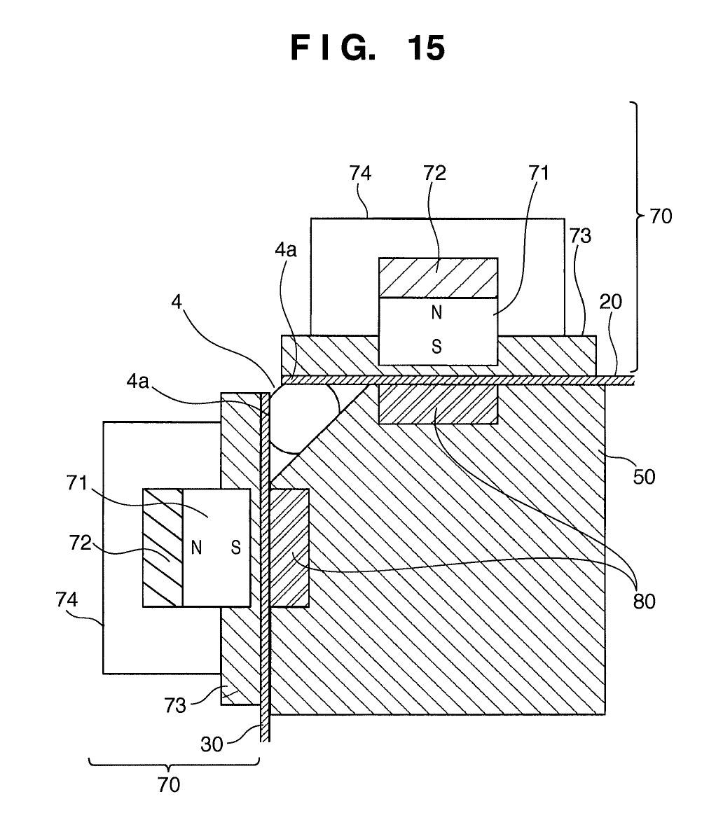

Also, although the column 50 is wholly made of a ferromagnetic material (FIG. 7) in the above-mentioned embodiment, it may be partially made of a ferromagnetic material. FIG. 15 exemplifies this case. The surface, adjacent to the magnets 71, of the column 50 shown in FIG. 15 is partially formed from a magnetic plate 80 made of a ferromagnetic material, and the remainder is made of a nonmagnetic material. The magnetic plate 80 need only have a thickness of about 5 mm to 10 mm to allow the magnets 71 to produce sufficiently large magnetic attractive forces. Magnetic plates 80 may be fixed on the columns 50 by, for example, bolts (not shown) or welding. The formation of the columns 50 in this way often conveniently circumvents restrictions of the material of the columns 50. Further, it is possible to reduce the weights of both the columns 50 and the structure 5.

Although the foregoing description has exemplified a case in which a vacuum vessel is formed from a pair of plate members which are formed by bending metal plates and are bonded to each other to form a closed space inside them, the present invention is not limited to this example. It is also possible to form a vacuum vessel 1 by, for example, three or more plate members.

A method of manufacturing a vacuum vessel 1 will be explained next.

As can be seen from FIGS. 1 and 2, a method of manufacturing a vacuum vessel 1 includes a step of disposing a structure 5. The method of manufacturing a vacuum vessel 1 also includes a step of interposing a sealing member 4 between the inner surfaces of bending members 20 and 30 and the outer surface of the structure 5 along the bonding portion between the bending members 20 and 30. The method of manufacturing a vacuum vessel 1 also includes a step of fixing the bending members 20 and 30 onto the structure 5 by disposing magnet units 70 in the outer peripheries of the surfaces of the bending members 20 and 30 on their atmospheric sides, and bonding the bending members 20 and 30 by pressing the sealing member 4.

The vacuum vessel 1 according to the above-mentioned embodiment has the following effects.

Since the vacuum vessel 1 is formed from the pair of bending members 20 and 30 made of relatively thin metal plates, it can be reduced in weight and manufactured without using a large metal material, unlike the prior art. Hence, according to this embodiment, it is possible to reduce the material cost of a vacuum vessel.

Also, since the magnetic attractive forces of the magnet units 70 are used as a means for fixing the bending members 20 and 30 and columns 50 serving as the structure in the vessel in preparation for sealing the bonding portion between the pair of bending members 20 and 30 by one sealing member 4 formed in a closed curve, it is unnecessary to employ welding in the process of manufacturing a vacuum vessel. This makes it possible to easily manufacture a vacuum vessel and transport it before assembly, and, in turn, makes it possible to facilitate handling of the vacuum vessel during its transportation.

Also, since the vacuum vessel can maintain airtightness reliably by squeezing the sealing member 4 as an O-ring using the magnetic attractive forces of the magnet units 70, it is easy to evacuate and has highly reliable vacuum performance. It is also possible to reduce the manufacturing cost of the vacuum vessel because of its simple structure.

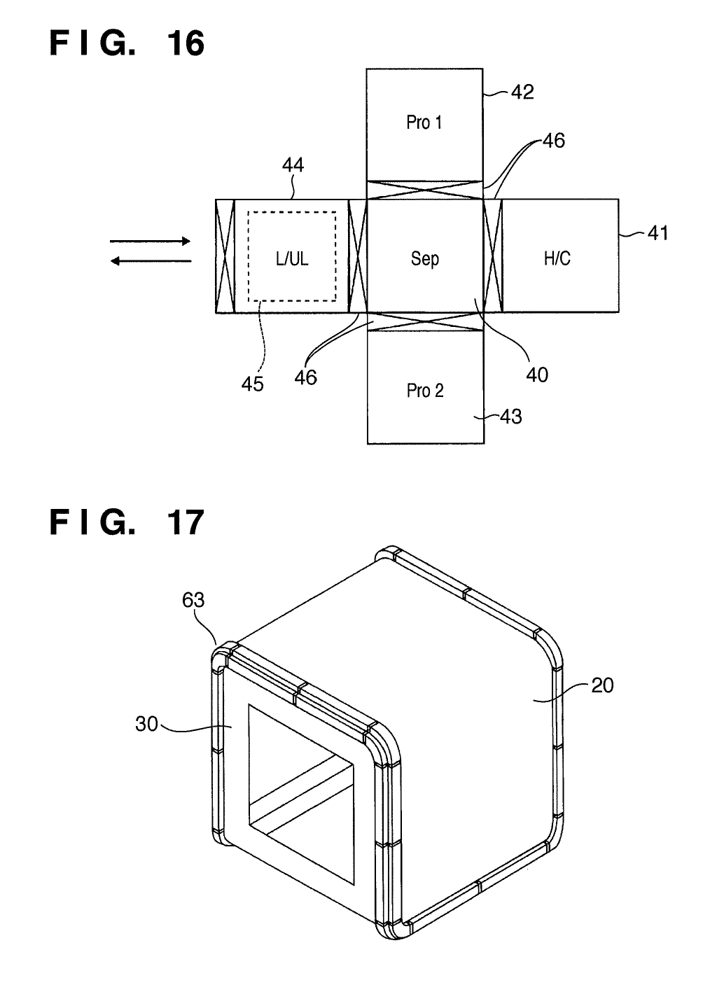

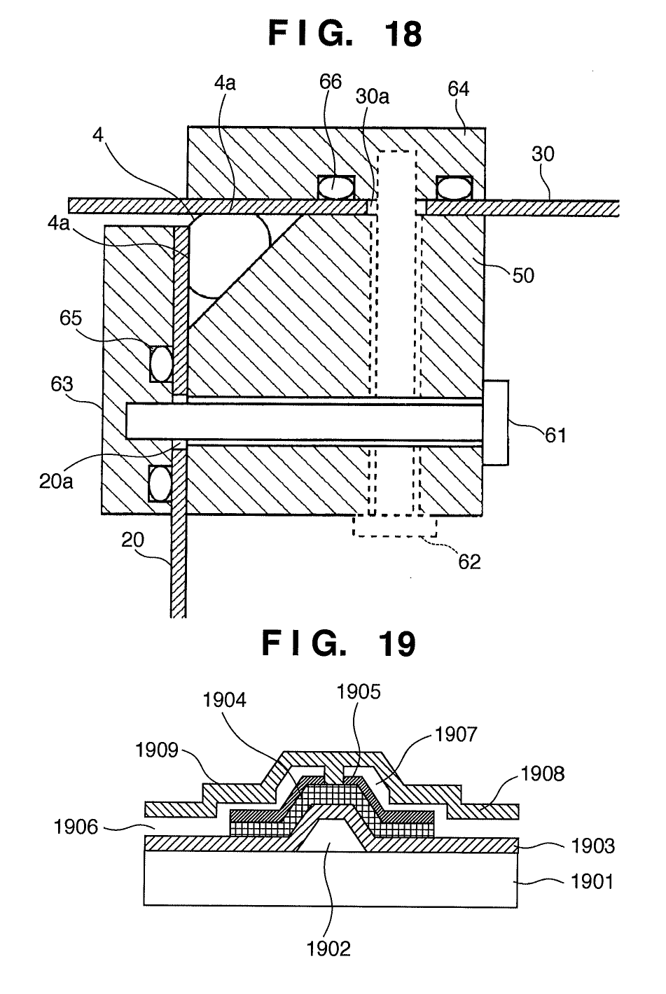

Also, the vacuum vessel 1 according to the above-mentioned embodiment is applicable to a vacuum processing apparatus which performs predetermined vacuum processing in a chamber. FIG. 16 illustrates an example of a vacuum processing apparatus including vacuum vessels 1 according to this embodiment.

As shown in FIG. 16, the vacuum processing apparatus serves as, for example, a single wafer processing type vacuum processing apparatus, and includes a vacuum processing chamber (Pro1) 42 for the first sputtering and a vacuum processing chamber (Pro2) 43 for the second sputtering. The vacuum processing apparatus also includes a separation chamber (Sep) 40, a heating/cooling chamber (H/C) 41 and a load/unload chamber (L/UL) 44. The separation chamber (Sep) 40 includes a substrate transfer mechanism. The separation chamber (Sep) 40, heating/cooling chamber (H/C) 41, vacuum processing chamber (Pro1) 42, and vacuum processing chamber (Pro2) 43 are formed using vacuum vessels 1 according to this embodiment, and the chambers 41 to 43 are adjacent to the separation chamber (Sep) 40 each.

The vacuum processing apparatus also includes: gate valves 46 which are disposed, (i) between a load/unload chamber (L/UL) 44 used for loading a substrate to be processed or unloading the processed substrate and the separation chamber (Sep) 40, (ii) between the separation chamber (Sep) 40 and the heating/cooling chamber (H/C) 41, (iii) between the vacuum processing chamber (Pro1) 42 and the separation chamber (Sep) 40, and (iV) between the vacuum processing chamber (Pro2) 43 and the separation chamber (Sep) 40.

The chambers 41, 42, 43, and 44 that constitute the vacuum processing apparatus are partitioned with the gate valve 46 so as to load and unload a substrate 45 as an object to be processed in a vacuum, that is, in a reduced-pressure atmosphere, and therefore can independently maintain their vacuums.

The substrate 45 loaded into the load/unload chamber (L/UL) 44 is transferred into the separation chamber 40 after an exhaust system (not shown) evacuates the load/unload chamber (L/UL) 44 to a predetermined pressure. Subsequently, the substrate 45 is transported from the separation chamber 40 into the heating/cooling chamber 41 and vacuum processing chambers 42 and 43 in accordance with various kinds of processes. After the vacuum processing is completed, the substrate 45 is unloaded from the load/unload chamber (L/UL) 44 through the separation chamber 40.

Although a sputtering deposition apparatus has been taken as an example of a vacuum processing apparatus in the above-mentioned embodiment, the deposition apparatus is not limited to the sputtering type. The vacuum processing apparatus according to this embodiment is applicable to a deposition apparatus which uses a deposition method such as the chemical vapor deposition method and to a processing apparatus such as an etching apparatus as well.

(Electronic Device Manufacturing Method)

A method of manufacturing a display device as an example of an electronic device using a sputtering apparatus as a vacuum processing apparatus according to the present invention will now be explained with reference to FIG. 19. FIG. 19 is a sectional view showing the cross-sectional structure of an a-Si TFT (Thin Film Transistor). In the method of manufacturing a display device, the deposition apparatus is used for the array manufacturing process and the BM (Black Matrix) manufacturing process.

In the array manufacturing process, a transistor and an interconnection are formed on a substrate 1901. Sputtering is mainly used in the following steps a, d, and e for deposition, and given layers are sequentially stacked in the following steps a to f:

Step a: Gate Electrode (e.g., Mo or Al) 1902

Step b: Gate Insulating Film (e.g., SiNₓ) 1903

Step c: Semiconductor Layers (e.g., a-Si or a-Si(n⁺)P) 1904 and 1905

Step d: Source/drain Electrodes (e.g., Mo or Al) 1906 and 1907

Step e: Transparent Electrode (e.g., ITO) 1908

Step f: Protective Film (e.g., SiNₓ) 1909

In the cross-sectional structure of a TFT shown in FIG. 19, a thin film suitable for a display device is formed by adjusting parameters such as the characteristics associated with a sputtering gas, the degree of vacuum, the substrate temperature, the discharge power, and the discharge time in accordance with the type of target as a thin-film material source in the above-mentioned steps a, d, and e.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-320829, filed Dec. 17, 2008, which is hereby incorporated by reference herein in its entirety.

1. A vacuum vessel including a plurality of plate members each of which is partially or wholly made of a metal and which are bonded to each other to form a closed space inside the plate members, and a sealing member which seals the bonding portion between the plate members, comprising:
a structure which is accommodated in the closed space, abuts against inner surfaces of the plate members and the sealing member, and is wholly or partially formed from a ferromagnetic body; and
a permanent magnet which is disposed on an outer surface of the plate member and presses the plate member against the sealing member by a magnetic attractive force acting on the ferromagnetic body of said structure.

2. A vacuum vessel including a pair of plate members which are formed by bending metal plates and are bonded to each other to form a closed space inside the plate members, and one sealing member which is formed in a closed curve and seals the bonding portion between the pair of plate members, comprising:
a structure which is accommodated in the closed space, abuts against inner surfaces of the plate members and the sealing member, and is wholly or partially formed from a ferromagnetic body; and
a permanent magnet which is disposed on an outer surface, opposite to the inner surface, of the plate member and presses the plate member against the sealing member by a magnetic attractive force acting on the ferromagnetic body of said structure.

3. The vessel according to claim 2, wherein the plate members form the closed space which forms a polyhedron, and are bent along creases which form sides of the polyhedron.

4. The vessel according to claim 2, wherein the sealing member is clamped by three surfaces: the inner surfaces of the pair of plate members which form the closed space and one side surface of said structure.

5. The vessel according to claim 2, wherein said permanent magnet is integrated with a metal plate in which not less than one through screw hole is formed, a screw having a length longer than a depth of the screw hole is inserted in the screw hole, and a direction of depth of the screw hole is perpendicular to the plate member.

6. The vessel according to claim 2, wherein said permanent magnet comprises a plurality of permanent magnets, and more than one of said plurality of permanent magnets is connected to a yoke of the ferromagnetic body to form a magnetic circuit.

7. The vessel according to claim 2, wherein the vacuum vessel comprises a cover which covers said permanent magnet.

8. A vacuum processing apparatus comprising:
a process chamber which comprises a vacuum vessel defined in claim 1 and processes an object under a reduced-pressure atmosphere in said vacuum vessel.

9. A vacuum vessel manufacturing method comprising:
a first step of bending metal plates to form a pair of plates which are bonded to each other to form a closed space inside the plate members;
a second step of accommodating, in the closed space, a structure which is wholly or partially formed from a ferromagnetic body and abuts against inner surfaces of the plate members, and interposing one sealing member, which is formed in a closed curve and seals the bonding portion between the pair of plate members, between the inner surfaces of the pair of plate members and an outer surface of the structure along the bonding portion; and
a third step of disposing a plurality of permanent magnets on outer surfaces, opposite to the inner surfaces, of the pair of plate members, and pressing the pair of plate members against the sealing member by magnetic attractive forces acting on the magnetic body of the structure.

10. An electronic device manufacturing method comprising a step of:
processing an object using a vacuum processing apparatus defined in claim 8.
